(19) United States
(12) Patent Application Publication
(10) Pub. No.: US 2024/0284719 A1
(43) Pub. Date: Aug. 22, 2024

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Can PENG, Shenzhen (CN)

(21) Appl. No.: 18/571,341

(22) PCT Filed: Dec. 20, 2021
(86) PCT No.: PCT/CN2021/139528

§ 371 Date: Dec. 18, 2023

(30) Foreign Application Priority Data
Dec. 13, 2021 (CN) 202111521476.6

(51) Int. Cl. H10K 59/122; H10K 59/173

(52) U.S. Cl. CPC H10K 59/122; H10K 59/173

(57) ABSTRACT

A display panel and a display device are provided, and a movement path of ink changes from a straight line to a curve, which increases a movement distance of the ink and narrows an area where the ink flows, thereby slowing down a movement speed of the ink, thus prevent a mura phenomenon due to ink concentrated in one place.

### TECHNICAL FIELD

The present application relates to a field of display technology, in particular to a display panel and a display device.

### BACKGROUND

At present, an organic light-emitting diode (OLED) is gradually expanding its market influence due to its special qualities such as low power consumption, fast response times, high contrast, wide color gamut, lightness and thinness, and applications for flexible display. At present, the main stream of mass-produced OLEDs is a fine metal mask (FMM) evaporation process, which can realize the mass production of small-sized OLED screens with high-resolution. In a field of large-sized OLED display, large-size evaporation adopts a stacked device structure, which has a complex process structure, low yield and high material cost, and is temporarily difficult to achieve low-cost preparation of OLED displays. Inkjet printing (IJP) for the OLED is an emerging OLED manufacturing process. Compared with the traditional evaporation process, inkjet printing for the OLED is performed by printing according to requirements for organic materials, which can achieve a material utilization rate of more than 90%. Inkjet printing for the OLED does not need to be carried out in a vacuum, and high-precision printing can be achieved as long as accuracy of a nozzle is controlled.

### SUMMARY OF INVENTION

### Technical Problem

At present, there are two designs of IJP OLED panels: an independent pixel design for each sub-pixel and a line bank design of connecting sub-pixels in a same row. Compared with the IJP OLED with independent pixel design for each sub-pixel, the line bank design provides a larger pixel opening area, a better ink leveling within a pixel, and a higher nozzle utilization rate of inkjet printing equipment, which can effectively increase an aperture ratio of a panel, pixel luminescence uniformity, inkjet printing process stability and a service life span of the panel, optical uniformity, and panel yield.

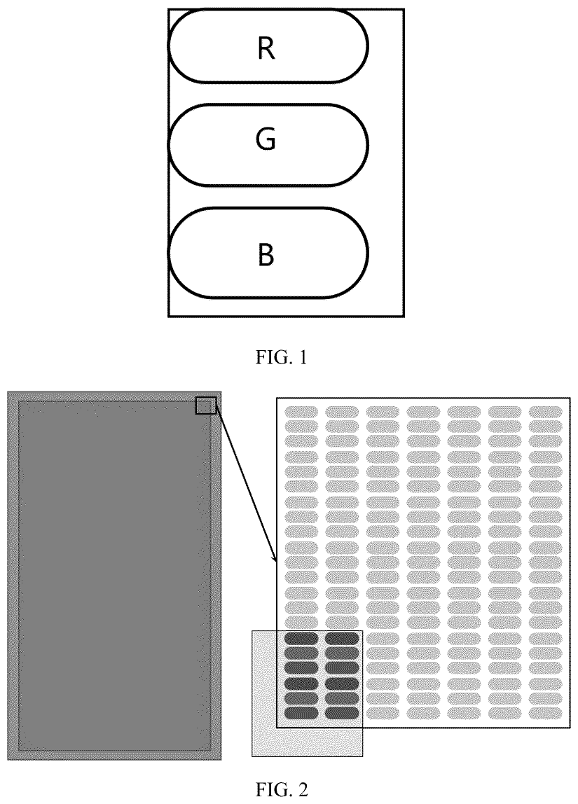

Referring to FIG. 1, FIG. 1 is a schematic diagram of sub-pixel units of independent pixel design for each sub-pixel provided by an embodiment of the present application. In the sub-pixel unit shown in FIG. 1, the sub-pixel unit may include three sub-pixel units of RGB, and the three sub-pixel units are arranged at intervals and independent from each other. FIG. 2 is a design diagram of a non-display area of independent pixel design for each sub-pixel provided by an embodiment of the present application. In FIG. 2, the sub-pixel units in the non-display area are as shown in FIG. 1, and are the sub-pixel units of independent pixel design for each sub-pixel.

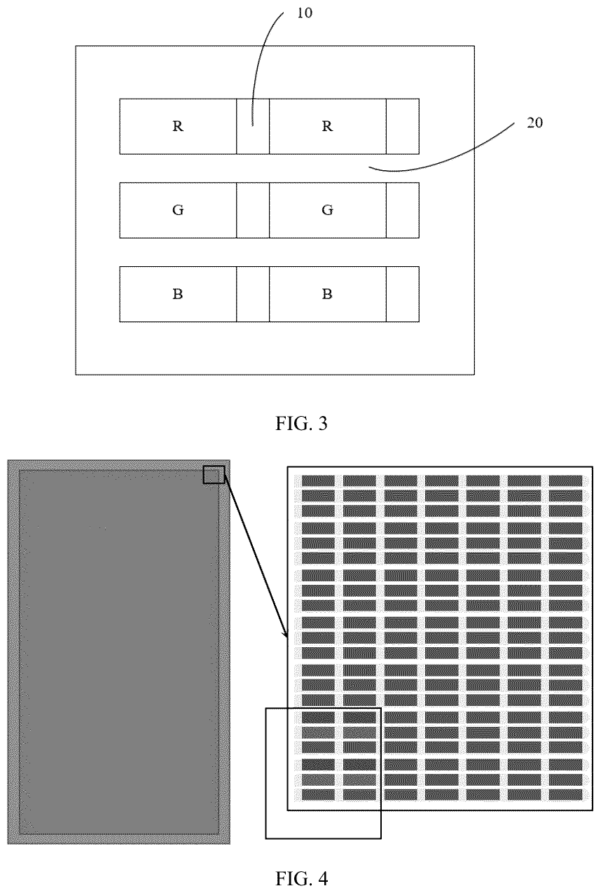

As shown in FIG. 3, FIG. 3 is a schematic diagram of sub-pixel units of line bank design provided by an embodiment of the present application. In the sub-pixel unit shown in FIG. 3, the sub-pixel unit also includes three sub-pixel units of RGB, but the three sub-pixel units are separated by first spacer layers 10 and second spacer layers 20. As shown in FIG. 4, FIG. 4 is a design diagram of the non-display area of a product of the line bank design provided by the embodiment of the present application; in FIG. 4, the sub-pixel units in the non-display area are as shown in FIG. 3, which are the sub-pixel units of the line bank design.

After the sub-pixel units are prepared by inkjet printing, vacuum drying is required. In the vacuum drying process, volatilization is faster at an outer side of the sub-pixel unit of independent pixel design for each sub-pixel, causing the ink inside the sub-pixel units to move outwards to result in a coffee ring effect, which in turn leads to uneven film surface at periphery of the pixels, while the film surface at an inner side of the pixels is normal, and a Mura phenomenon with obvious internal and external differences occurs in the macroscopic view. Compared with the independent pixel design for each sub-pixel, in the panel of the line bank design, uneven drying of the film surface is aggravated due to the ink flow in an extending direction of the spacer layers, resulting in uneven film formation, and further results in a wider width of the non-display area, which is not conducive to development of narrow bezel and borderless products.

### Problem Solution

### Technical Solution

The present application aims to provide a sub-pixel unit and a device panel, which are intended to solve the problem that the film of the pixel unit is formed unevenly to result in too wide non-display region and the unconducive design of a narrow side frame in the prior art.

In a first aspect, an embodiment of the present application provides a sub-pixel unit including:

a display panel includes a plurality of first spacer layers extending in a first direction and a plurality of second spacer layers extending in a second direction, the first spacer layers and the second spacer layers define a plurality of sub-pixel units, the plurality of second spacer layers are configured to separate the sub-pixel units of different colors, and the first direction is perpendicular to the second direction;

a protrusion is formed on at least one of the plurality of second spacer layers, and the protrusion is protruded in one of the sub-pixel units.

In a possible embodiment, the plurality of first spacer layers are configured to separate the plurality of sub-pixel units located in a same row; the plurality of sub-pixel units located in the same row have a same color; and colors corresponding to the plurality of sub-pixel units located in a same column are arranged cyclically.

In a possible embodiment, each of the first spacer layers is located between adjacent ones of the sub-pixel units in the same row, and each of the second spacer layers is located between adjacent ones of the sub-pixel units in the same column; the plurality of first spacer layers form a first channel in the display panel, the plurality of second spacer layers form a second channel in the display panel, and a protruding direction of the protrusion is same as an extending direction of the first channel.

In a possible embodiment, the protrusion is formed on all of the second spacer layers.

In a possible embodiment, each of the second spacer layers includes a protruding portion and a flat portion, the protruding portion is protruded in each of the sub-pixel units, and the flat portion is connected to the second channel.

In a possible embodiment, protruding directions of at least two protruding portions of the plurality of protrusions disposed in the plurality of second spacer layers in the same row are different.

In a possible embodiment, protruding directions of at least two protruding portions of the plurality of protrusions disposed in the plurality of second spacer layers in the same column are same.

In a possible embodiment, the first spacer layers are made of a hydrophilic material, and the second spacer layers are made of a hydrophobic material.

In a possible embodiment, the protrusion is semicircular, semi-elliptical or rectangular.

In a possible embodiment, a groove is formed inside each of the sub-pixel units, and a shape of the groove and a shape of the protrusion are matched with each other.

In a second aspect, an embodiment of the present application provides a display device including the display panel as described in any one of the above embodiments; the display panel includes a plurality of first spacer layers extending in a first direction and a plurality of second spacer layers extending in a second direction, the first spacer layers and the second spacer layers define a plurality of sub-pixel units, the plurality of second spacer layers are configured to separate the sub-pixel units of different colors, and the first direction is perpendicular to the second direction;

a protrusion is formed on at least one of the plurality of second spacer layers, and the protrusion is protruded in one of the sub-pixel units.

In a possible embodiment, the plurality of first spacer layers are configured to separate the plurality of sub-pixel units located in a same row; the plurality of sub-pixel units located in the same row have a same color; and colors corresponding to the plurality of sub-pixel units located in a same column are arranged cyclically.

In a possible embodiment, each of the first spacer layers is located between adjacent ones of the sub-pixel units in the same row, and each of the second spacer layers is located between adjacent ones of the sub-pixel units in the same column; the plurality of first spacer layers form a first channel in the display panel, the plurality of second spacer layers form a second channel in the display panel, and a protruding direction of the protrusion is same as an extending direction of the first channel.

In a possible embodiment, the protrusion is formed on all of the second spacer layers.

In a possible embodiment, each of the second spacer layers includes a protruding portion and a flat portion, the protruding portion is protruded in each of the sub-pixel units, and the flat portion is connected to the second channel.

In a possible embodiment, protruding directions of at least two protruding portions of the plurality of protrusions disposed in the plurality of second spacer layers in the same row are different.

In a possible embodiment, protruding directions of at least two protruding portions of the plurality of protrusions disposed in the plurality of second spacer layers in the same column are same.

In a possible embodiment, the first spacer layers are made of a hydrophilic material, and the second spacer layers are made of a hydrophobic material.

In a possible embodiment, the protrusion is semicircular, semi-elliptical or rectangular.

In a possible embodiment, a groove is formed inside each of the sub-pixel units, and a shape of the groove and a shape of the protrusion are matched with each other.

### Beneficial Effects of Invention

### Beneficial Effects

The present application provides a display panel and a display device. The display panel includes a plurality of first spacer layers extending in a first direction and a plurality of second spacer layers extending in a second direction. The plurality of second spacer layers are configured to separate the sub-pixel units of different colors, and the first direction is perpendicular to the second direction; wherein a protrusion is formed on any one of the plurality of second spacer layers, and the protrusion is protruded in the sub-pixel unit. Ink in the sub-pixel units flows near a channel formed by the second spacer layers and the protrusions during vacuum drying, a movement path of ink changes from a straight line to a curve, which increases a movement distance of the ink and narrows an area where the ink flows, thereby slowing down a movement speed of the ink, thus prevent a mura phenomenon due to ink concentrated in one place.

### BRIEF DESCRIPTION OF DRAWINGS

### Description of Drawings

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

FIG. 1 is a schematic diagram of an embodiment of a sub-pixel unit of an independent pixel design for each sub-pixel provided by an embodiment of the present application.

FIG. 2 is a design diagram of a non-display area of the independent pixel design for each sub-pixel provided by an embodiment of the present application.

FIG. 3 is a schematic diagram of a sub-pixel unit of a line bank design provided by an embodiment of the present application.

FIG. 4 is a design diagram of a non-display area of a product of the line bank design provided by an embodiment of the present application.

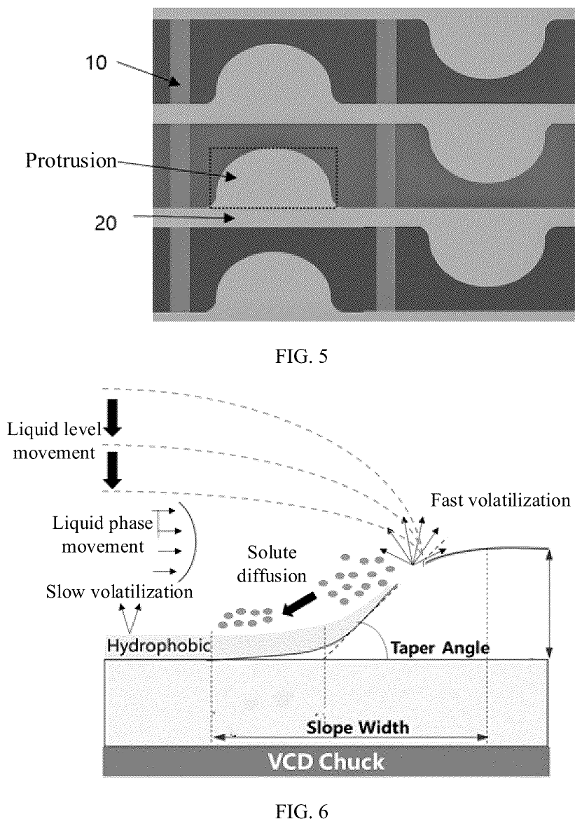

FIG. 5 is a schematic diagram of a display panel provided by an embodiment of the present application.

FIG. 6 is a schematic diagram of vacuum drying provided by an embodiment of the present application.

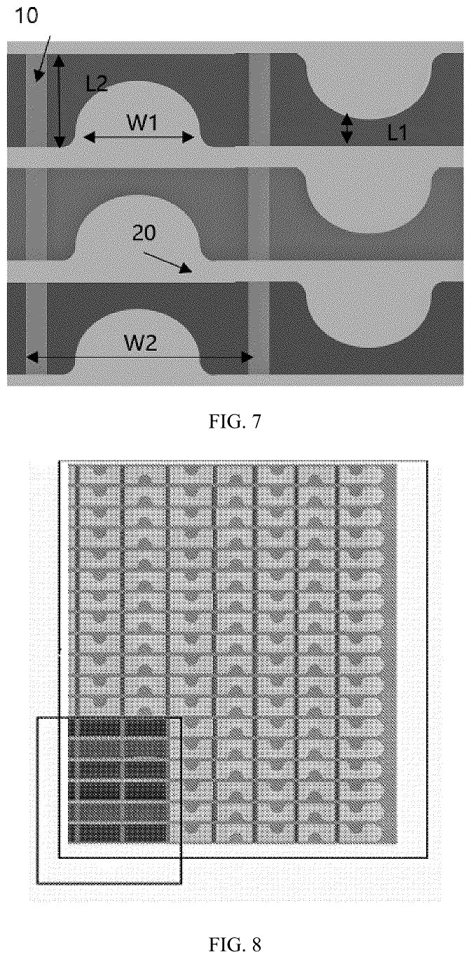

FIG. 7 is a schematic diagram of a display panel provided by another embodiment of the present application.

FIG. 8 is a design diagram of a non-display area of a product prepared by a display panel provided by an embodiment of the present application.

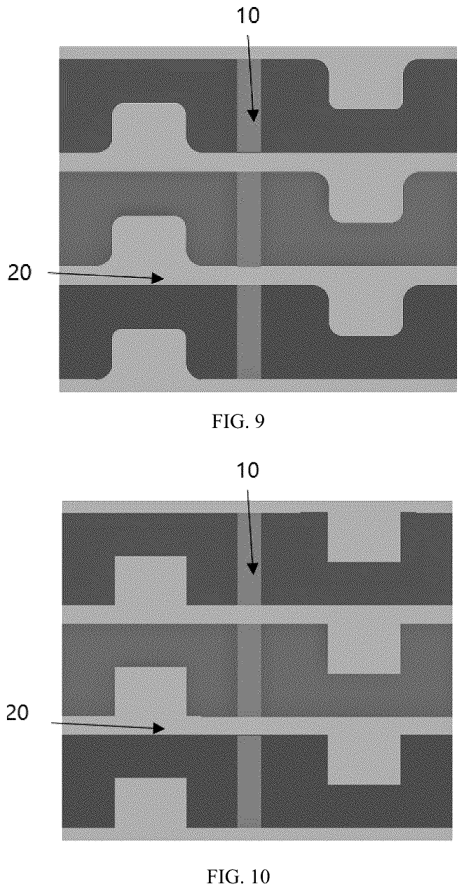

FIG. 9 is a schematic diagram of a display panel provided by another embodiment of the present application.

FIG. 10 is a schematic diagram of a display panel provided by a further embodiment of the present application.

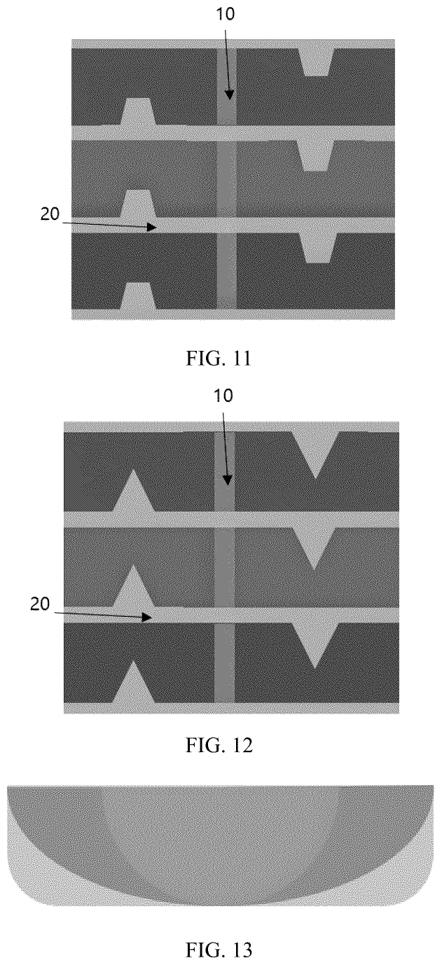

FIG. 11 is a schematic diagram of a display panel provided by another embodiment of the present application.

FIG. 12 is a schematic diagram of a display panel provided by a further embodiment of the present application.

FIG. 13 is a schematic diagram of a plurality of grooves of different shapes provided by an embodiment of the present application.

### INVENTION EMBODIMENTS

### Implementation of the Present Invention

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In the description of this application, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside” and the like are based on the orientation or positional relationship shown in the drawings, and is merely for the convenience of describing the present invention and simplifying the description, rather than indicating or implying that the device or element referred to must have a specific orientation, structure and operation in a specific orientation, which should not be construed as limitations on the present invention. In addition, the terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless specifically defined otherwise.

In the present application, the term “exemplary” is used to mean “serving as an example, illustration, or description.” Any embodiment described as “exemplary” in the present application is not necessarily to be construed as preferred or advantageous over other embodiments. In order to enable any person skilled in the art to implement and use the present invention, the following description is given. In the following description, details are set forth for the purpose of explanation. It should be understood by one of ordinary skill in the art that the present invention may be implemented without the use of these specific details. In other embodiments, well-known structures and procedures are not described in detail to avoid obscuring the description of the present invention with unnecessary details. Accordingly, the present invention is not intended to be limited to the embodiments shown, but is to be accorded the widest scope consistent with the principles and features disclosed herein.

It should be noted that, since the methods provided by the embodiments of the present application are executed in electronic devices, and processing objects of each of the electronic devices exist in a form of data or information, such as time, which is essentially time information, it is appreciated that a size, a quantity, a location, etc. that are mentioned in the subsequent embodiments exist in the form of corresponding data for the electronic devices to process, and the details are not repeated herein for brevity.

Embodiments of the present application provide a display panel and a display device, which will be described in detail below.

The display panel provided by the present application is improved on the basis of sub-pixel units of the line bank design as shown in FIG. 3.

As shown in FIG. 5, FIG. 5 is a schematic diagram of an embodiment of a display panel provided by an embodiment of the present application. The display panel shown in FIG. 5 includes a plurality of first spacer layers extending in a first direction and a plurality of second spacer layers extending in a second direction. The plurality of first spacer layers and the plurality of second spacer layers define a plurality of sub-pixel units, and the plurality of second spacer layers are configured to separate sub-pixel units of different colors, and the first direction is perpendicular to the second direction.

That is, the plurality of first spacer layers 10 and the plurality of second spacer layers 20 intersect perpendicularly to each other to form a plurality of accommodating spaces, and the sub-pixel unit is formed in each of the plurality of accommodating spaces by inkjet printing; that is, the sub-pixel units is multiple. In an actual display panel, a plurality of sub-pixel units are usually arranged in an array, so the plurality of first spacer layers 10 and the plurality of second spacer layers 20 intersect each other to form the plurality of accommodating spaces arranged in an array of multiple rows and multiple columns for accommodation of the sub-pixel units.

Generally, the plurality of sub-pixel units are arranged in an array, and the plurality of sub-pixel units are separated by the plurality of first spacer layers 10 and the plurality of second spacer layers 20. Moreover, in an embodiment of the present application, a protrusion is formed on any one of the plurality of second spacer layers 20, and a groove is formed inside each of the sub-pixel units, so that the protrusion on the second spacer layers 20 is filled in the groove inside the sub-pixel units; that is, the protrusion is protruded in one of the sub-pixel units

In an actual display panel, the film structure corresponding to the sub-pixel units is a flat layer with a certain thickness, and the display panel also includes other film structures under the layer corresponding to the sub-pixel units, so the first spacer layers 10 and the second spacer layers 20 are actually arranged above the other film structures in the display panel, and the first spacer layers 10 and the second spacer layers 20 intersect each other to form a plurality of accommodating spaces for forming sub-pixel units. The sub-pixel unit has a flat film structure with a certain thickness, so the protrusion formed on the second spacer layers 20 can be protruded inside the sub-pixel units.

An embodiment of the present application provides a display panel including a plurality of first spacer layers extending in a first direction and a plurality of second spacer layers extending in a second direction, and the plurality of second spacer layers are configured to separate the sub-pixel units of different colors; and the first direction is perpendicular to the second direction. Meanwhile, the protrusion is provided on any one of the second spacer layers, and the protrusion is protruded in the sub-pixel unit. Ink in the sub-pixel units flows near a channel formed by the second spacer layers and the protrusions during vacuum drying, a movement path of ink changes from a straight line to a curve, which increases a movement distance of the ink and narrows an area where the ink flows, thereby slowing down a movement speed of the ink, thus prevent a mura phenomenon due to ink concentrated in one place.

In an embodiment of the present application, the first spacer layers 10 and the second spacer layers 20 intersect each other to form a plurality of accommodating spaces, and the sub-pixel unit is formed in each of the plurality of accommodating spaces. In addition, in an actual display panel, a sub-pixel unit usually includes a plurality of sub-pixel units; the plurality of sub-pixel units are usually arranged in an array of multiple rows and multiple columns. The plurality of sub-pixel units located in a same row have a same color, and colors corresponding to the plurality of sub-pixel units located in different rows are arranged cyclically.

In the embodiment shown in FIG. 5, the display panel may include the plurality of sub-pixel units. Specifically, it may include three kinds of sub-pixel units of RGB. The plurality of sub-pixel units located in the same row are all R sub-pixel units, or all G sub-pixel units, or all B sub-pixel units. The plurality of sub-pixel units located in the same column can be cyclically arranged in an order of RGB. In other embodiments of the present application, the display panel may also include four kinds of sub-pixel units of RGBW, and the plurality of sub-pixel units in the same row are all R sub-pixel units, or all G sub-pixel units, or all B sub-pixel units, or all W sub-pixel units. The plurality of sub-pixel units located in the same column can be cyclically arranged in an order of RGBW.

Meanwhile, in the embodiment of the present application, the plurality of first spacer layers 10 are located between the plurality of sub-pixel units in the same row, and the plurality of second spacer layers 20 are located between the plurality of sub-pixel units in the same column. The plurality of first spacer layers 10 form a first channel in the display panel, and the plurality of second spacer layers 20 form a second channel in the display panel. A protruding direction of the protrusion is the same as the extending direction of the first channel. Considering that the first spacer layers 10, the second spacer layers 20, and the sub-pixel units are actually all three-dimensional structures, the protrusions on the second spacer layers 20 are not actually protruded on a plane where the entire display panel is located.

In an actual display panel, the second spacer layers 20 may include up, down, left, right, front, and back surfaces, that is, a total of six surfaces. The protrusion is actually arranged on one of the six surfaces of the second spacer layer 20 close to one of the sub-pixel units, and is protruded inside the sub-pixel unit. The schematic diagram shown in FIG. 5 is actually a top view of a structure of the display panel. When observing a cross-sectional structure of the display panel, in fact, a cross-sectional view of the display panel does not show the protrusion.

Meanwhile, a groove corresponding to the protrusion is formed inside the sub-pixel unit, and an opening direction of the groove is the same as the extending direction of the first spacer layers 10; that is, the protruding direction of the protrusion is the same as the extending direction of the first channel formed by the first spacer layer.

Referring to FIG. 5, specifically, in the embodiment shown in FIG. 5, the first spacer layers 10 are arranged in the vertical direction to space a plurality of sub-pixel units in the same row, and the second spacer layers 20 are arranged in the horizontal direction to space the plurality of sub-pixel units in the same column. The protruding direction of the protrusions provided on the second spacer layers is the same as that of the first spacer layers 10; that is, the protrusions are provided along the vertical direction. In this way, the prepared second spacer layers 20 can be filled inside the groove; in this case, the second spacer layers 20 include not only the original linear part, but also the part filled in the sub-pixel unit (or the accommodating space).

Of course, since the vertical direction includes two different directions, upward and downward; therefore, when there are a plurality of protrusions, the plurality of protrusions can be arranged upward in the vertical direction or downward in the vertical direction.

In an embodiment of the present application, the second spacer layers 20 may include a protruding portion and a flat portion, and the flat portion is actually connected to the second channel, and the protruding portion is protruded on the flat portion and protruded inside the sub-pixel unit. The grooves described in the embodiments of the present application are all arranged inside the sub-pixel unit, and the protrusions on the second spacer layers 20 are filled inside the grooves, and the protrusions formed by the filling of the second spacer layers 20 will not be formed at the outer side of the sub-pixel units.

In an embodiment of the present application, the first spacer layers 10 and the second spacer layers 20 are usually made of organic materials, but the first spacer layers 10 are made of hydrophilic materials, and the second spacer layers 20 are made of hydrophobic materials. The second spacer layers 20 made of hydrophobic material can isolate inks of different colors and avoid color mixing. Meanwhile, the second spacer layers 20 made of hydrophobic material make the ink of inkjet printing flow along the edge of the second spacer layers 20 during subsequent vacuum drying without penetrating into the inside of the second spacer layers 20.

In an embodiment of the present application, a groove is formed on the sub-pixel units, and the protruding portion on the second spacer layers 20 is filled inside the groove, so that when vacuum drying is performed, the flow path of ink for inkjet printing is changed from the original straight line to curve, increasing the distance the ink flows. In this way, under the same drying conditions and drying time, the distance that the ink moves is reduced; the ink is not easy to move from the center to the edge of the sub-pixel unit, thereby reducing the mura phenomenon.

Further, since the sub-pixel units in the present application are arranged in the non-display area of the display panel, and the sub-pixel units in the present application can be used to reduce abnormal sub-pixel units, thereby reducing the width of the non-display area, so as to achieve a panel design with a narrow bezel.

As shown in FIG. 6, FIG. 6 is a schematic diagram of vacuum drying provided in an embodiment of the present application; wherein “hydrophobic” means that the spacer layer is made of a hydrophobic material, and “taper angle” refers to a size of an inclination angle formed by the spacer layer made in an embodiment of the present application, “slope width” refers to a width of a slope corresponding to the formed protrusion. In FIG. 6, under an original dry condition of the ink, a volatilization rate of the ink at an outer side is faster. After the solution evaporates, the ink in a center of the pixel will move to an edge, and the replenished ink will exacerbate a coffee ring effect, which in turn leads to uneven film surface at periphery of the pixels. With the sub-pixel units provided by the embodiment of the present application, a groove is formed in the sub-pixel units on the side close to the second spacer layers 20, and the second spacer layers fill the inside of the groove to form a protrusion. The protruding part of the second spacer layers 20 will cause resistance to the flow of ink, hinder the flow of ink from the center of the pixel to the edge, and reduce the flow rate of the ink, thereby reducing the problem of uneven pixel film surface.

It should be noted that, in an embodiment of the present application, protrusions are formed on the second spacer layers to protrude inside the sub-pixel units, so that grooves are formed inside the sub-pixel units, and the channel formed by the second spacer layers 20 is changed. The ink drips near the second spacer layers 20 and flows inside the sub-pixel units; when the channel formed by the second spacer layers 20 changes, a flow path of the ink will also change accordingly.

As shown in FIG. 7, FIG. 7 is a schematic diagram of the display panel provided by another embodiment of the present application. Referring to FIGS. 5 and 7 in conjunction, in the display panel in an embodiment of the present application, the sizes of the first spacer layers 10, the second spacer layers 20, the protrusions, and the sub-pixels in the display panel need to comply with preset size conditions.

In FIG. 7, a width of each of the first spacer layers 10 in the vertical direction is L2, that is, the width of each of the sub-pixel units in the vertical direction is L2; and a width of each of the sub-pixel units in the vertical direction is L1 after deducting the groove portion. Meanwhile, in the pixel of a same row, a length of any one of the sub-pixel units in the horizontal direction is W2, and a length of any one of grooves in the horizontal direction is W1.

In an embodiment of the present application, when L1/L2 is greater than a first preset value, it can be considered that the channel through which the ink flows in the vertical direction is wider; in this case, the channel needs to be kept short, that is, W1/W2 is smaller than a second preset value.

The first preset value may be 55%, and the second preset value may be 35%. That is, when L1/L2 is greater than 55%, it is considered that the channel through which the ink flows in the vertical direction is wider; and when W1/W2 is less than 35%, it is considered that the channel through which the ink flows in the vertical direction is shorter.

When L1/L2 is less than a third preset value, it can be considered that the channel through which the ink flows is relatively narrow; in this case, the channel needs to be kept longer, that is, W1/W2 is greater than a fourth preset value.

The third preset value may be 40%, and the fourth preset value may be 50%. That is, when L1/L2 is less than 40%, it is considered that the channel through which the ink flows in the vertical direction is relatively narrow; and when W1/W2 is greater than 50%, it is considered that the channel through which the ink flows in the vertical direction is longer.

In an embodiment of the present application, each of the sub-pixel units is usually prepared as a narrow and long structure, so that in the same time, the channel through which the ink flows is narrower, and a flow distance of the ink becomes longer, which can effectively slow down a flow rate of the ink.

In a specific embodiment, L1 may be 14 μm, and L2 may be 48 μm; and W1 may be 136 μm, and W2 may be 186 μm. In this case, L1/L2 is approximately equal to 30%, and under the premise that L1/L2 is less than 40%, W1/W2 is approximately equal to 73%, which is greater than 50%.

As shown in FIG. 8, FIG. 8 is a design diagram of a non-display area of a product prepared by a display panel provided by an embodiment of the present application. Referring to FIG. 5, FIG. 7 and FIG. 8 in conjunction. In the embodiment shown in FIG. 8, protruding directions of at least two protruding portions of the plurality of protrusions disposed in the plurality of second spacer layers in the same row are different; and a position on each of the sub-pixel units corresponding to each of the protrusions may correspondingly form one of the grooves, so opening directions corresponding to the grooves are also different.

In the embodiment shown in FIG. 5, the plurality of protrusions in different protruding directions in the plurality of second spacer layers located in the same row may intersect each other. In this case, a plurality of grooves with different opening directions located in the same row may also intersect each other. Meanwhile, in the embodiment shown in FIG. 5, the protruding directions of at least two of the plurality of protrusions provided in the plurality of second spacers in the same column may be the same. Correspondingly, the opening directions of at least two of the plurality of grooves located in the same row may also be the same. Specifically, the plurality of protrusions located in the same column may be arranged upward in the vertical direction at the same time, or the plurality of protrusions may be arranged downward in the vertical direction at the same time. In this case, the plurality of grooves located in the same row may simultaneously open downwards or simultaneously open upwards.

Referring to FIG. 5 and FIG. 6, when a plurality of protrusions are formed, if vacuum drying is performed, a part of the second spacer layers 20 filled in the groove with the opening downward will block the flow of ink. Meanwhile, the part of the second spacer layers 20 filled in the groove with the opening downward narrows the channel through which the ink flows, so that a volume of the ink flowing through the channel in a same duration of time becomes smaller. In an embodiment of the present application, the protrusions in different protruding directions intersecting each other can further reduce a flow speed of the ink.

In the embodiments of the present application, the protrusions can be in various shapes such as a semicircle, a semi-ellipse, a rectangle, a rounded rectangle, a triangle, and a trapezoid, and the shapes and sizes of the protrusions can be adjusted according to actual requirements for an aperture ratio of the pixel.

As shown in FIG. 9, FIG. 9 is a schematic diagram of the display panel provided by another embodiment of the present application. In FIG. 9, the shape of the protrusion can be a rounded rectangle; that is, four corners of the rectangle are arcs. FIG. 10 is a schematic diagram of a display panel provided by a further embodiment of the present application. In FIG. 10, the shape of the protrusion may be a rectangle. In the embodiments shown in FIGS. 11 and 12, the shapes of the protrusions are trapezoidal and triangular, respectively. Of course, In an embodiment of the present application, a shape of the groove and a shape of the protrusion are matched with each other, and when the protrusion is a rectangle with rounded corners, a protrusion of the groove is also a rectangle with rounded corners.

In an embodiment of the present application, an object is to increase the flow path of the ink and set a barrier to inhibit the flow of the ink; that is, to increase a loss of the ink during the ink flows. Specifically, the loss of the ink along the flow path can satisfy the following formula: loss along the flow path L=k/r−(k*X)/A.

In the above formula, k is a fixed parameter, and the parameter k varied with different display panels; r is a hydraulic radius, which refers to a ratio of a flow area of a certain liquid delivery section to a side length of a liquid delivery pipeline (i.e. a wet circumference) that is in contact with a liquid body, and r is related to a shape of a section and is often used to calculate a liquid delivery capacity of a channel tunnel.

Therefore, r=X/A, where A is an effective section through which the liquid flows, and X is the wet circumference. The grooves with different shapes correspond to different effective cross-sections and wet circumferences.

In the embodiments of the present application, when the shape of the protrusion is semicircular or semi-elliptical, it has a small effect on a flow rate of the ink; and when the shape of the protrusion is triangular or rectangular, it has a more obvious inhibitory effect on the flow rate of the ink.

Referring to FIG. 13, FIG. 13 is a schematic diagram of a plurality of grooves of different shapes provided by an embodiment of the present application. In FIG. 13, sizes of the grooves of various shapes in the vertical direction are the same, that is, channel widths corresponding to the grooves of various shapes are the same. On the premise of the same channel width, when the shape of the groove is a rounded rectangle, the wet circumference X corresponding to the groove is the largest, that is, a distance through which the ink flows is the largest. In this way, in the same time, the ink is less likely to spread from the center.

It should be noted that, in an embodiment of the present application, the ink flows inside the accommodating space formed by the intersection of the first spacer layers 10 and the second spacer layers 20, instead of flowing inside the channel formed by the first spacer layers 10 and the second spacer layers 20.

That is, in an embodiment of the present application, not only the size of the groove, but also the specific shape of the groove need to be considered; the size of the groove and the specific shape of the groove will affect the flow of ink.

An embodiment of the present application also provides a display device, which includes the sub-pixel units as described in the above embodiment. Specifically, the display panel shown in FIG. 5 includes a plurality of first spacer layers extending in a first direction and a plurality of second spacer layers extending in a second direction. The plurality of first spacer layers and the plurality of second spacer layers define a plurality of sub-pixel units, and the plurality of second spacer layers are configured to separate sub-pixel units of different colors, and the first direction is perpendicular to the second direction.

That is, the plurality of first spacer layers 10 and the plurality of second spacer layers 20 intersect perpendicularly to each other to form a plurality of accommodating spaces, and the sub-pixel unit is formed in each of the plurality of accommodating spaces by inkjet printing; that is, the sub-pixel units is multiple. In an actual display panel, a plurality of sub-pixel units are usually arranged in an array, so the plurality of first spacer layers 10 and the plurality of second spacer layers 20 intersect each other to form the plurality of accommodating spaces arranged in an array of multiple rows and multiple columns for accommodation of the sub-pixel units.

Generally, the plurality of sub-pixel units are arranged in an array, and the plurality of sub-pixel units are separated by the plurality of first spacer layers 10 and the plurality of second spacer layers 20. Moreover, In an embodiment of the present application, a protrusion is formed on any one of the plurality of second spacer layers 20, and a groove is formed inside each of the sub-pixel units, so that the protrusion on the second spacer layers 20 is filled in the groove inside the sub-pixel units; that is, the protrusion is protruded in one of the sub-pixel units

In an actual display panel, the film structure corresponding to the sub-pixel units is a flat layer with a certain thickness, and the display panel also includes other film structures under the layer corresponding to the sub-pixel units, so the first spacer layers 10 and the second spacer layers 20 are actually arranged above the other film structures in the display panel, and the first spacer layers 10 and the second spacer layers 20 intersect each other to form a plurality of accommodating spaces for forming sub-pixel units. The sub-pixel unit has a flat film structure with a certain thickness, so the protrusion formed on the second spacer layers 20 can be protruded inside the sub-pixel units.

An embodiment of the present application provides a display panel including a plurality of first spacer layers extending in a first direction and a plurality of second spacer layers extending in a second direction, and the plurality of second spacer layers are configured to separate the sub-pixel units of different colors; and the first direction is perpendicular to the second direction. Meanwhile, the protrusion is provided on any one of the second spacer layers, and the protrusion is protruded in the sub-pixel unit. Ink in the sub-pixel units flows near a channel formed by the second spacer layers and the protrusions during vacuum drying, a movement path of ink changes from a straight line to a curve, which increases a movement distance of the ink and narrows an area where the ink flows, thereby slowing down a movement speed of the ink, thus prevent a mura phenomenon due to ink concentrated in one place.

In an embodiment of the present application, the first spacer layers 10 and the second spacer layers 20 intersect perpendicularly to each other to form a plurality of accommodating spaces, and the sub-pixel unit is formed in each of the plurality of accommodating spaces. In addition, in an actual display panel, a sub-pixel unit usually includes a plurality of sub-pixel units; the plurality of sub-pixel units are usually arranged in an array of multiple rows and multiple columns. The plurality of sub-pixel units located in a same row have a same color, and colors corresponding to the plurality of sub-pixel units located in different rows are arranged cyclically.

In the embodiment shown in FIG. 5, the display panel may include the plurality of sub-pixel units, specifically, it may include three kinds of sub-pixel units of RGB. The plurality of sub-pixel units located in the same row are all R sub-pixel units, or all G sub-pixel units, or all B sub-pixel units. The plurality of sub-pixel units located in the same column can be cyclically arranged in an order of RGB. In other embodiments of the present application, the display panel may also include four kinds of sub-pixel units of RGBW, and the plurality of sub-pixel units in the same row are all R sub-pixel units, or all G sub-pixel units, or all B sub-pixel units, or all W sub-pixel units. The plurality of sub-pixel units located in the same column can be cyclically arranged in an order of RGBW.

Meanwhile, in the embodiment of the present application, the plurality of first spacer layers 10 are located between the plurality of sub-pixel units in the same row, and the plurality of second spacer layers 20 are located between the plurality of sub-pixel units in the same column. The plurality of first spacer layers 10 form a first channel in the display panel, and the plurality of second spacer layers 20 form a second channel in the display panel. A protruding direction of the protrusion is the same as the extending direction of the first channel. Considering that the first spacer layers 10, the second spacer layers 20, and the sub-pixel units are actually all three-dimensional structures, the protrusions on the second spacer layers 20 are not actually protruded on a plane where the entire display panel is located.

In an actual display panel, the second spacer layers 20 may include up, down, left, right, front, and back surfaces, that is, a total of six surfaces. The protrusion is actually arranged on one of the six surfaces of the second spacer layer 20 close to one of the sub-pixel units, and is protruded inside the sub-pixel unit. The schematic diagram shown in FIG. 5 is actually a top view of a structure of the display panel. When observing a cross-sectional structure of the display panel, in fact, a cross-sectional view of the display panel does not show the protrusion.

Meanwhile, a groove corresponding to the protrusion is formed inside the sub-pixel unit, and an opening direction of the groove is the same as the extending direction of the first spacer layers 10; that is, the protruding direction of the protrusion is the same as the extending direction of the first channel formed by the first spacer layer.

Referring to FIG. 5, specifically, in the embodiment shown in FIG. 5, the first spacer layers 10 are arranged in the vertical direction to space a plurality of sub-pixel units in the same row, and the second spacer layers 20 are arranged in the horizontal direction to space the plurality of sub-pixel units in the same column. The protruding direction of the protrusions provided on the second spacer layers is the same as that of the first spacer layers 10; that is, the protrusions are provided along the vertical direction. In this way, the prepared second spacer layers 20 can be filled inside the groove; in this case, the second spacer layers 20 include not only the original linear part, but also the part filled in the sub-pixel unit (or the accommodating space).

Of course, since the vertical direction includes two different directions, upward and downward; therefore, when there are a plurality of protrusions, the plurality of protrusions can be arranged upward in the vertical direction or downward in the vertical direction.

In an embodiment of the present application, the second spacer layers 20 may include a protruding portion and a flat portion, and the flat portion is actually connected to the second channel, and the protruding portion is protruded on the flat portion and protruded inside the sub-pixel unit. The grooves described in the embodiments of the present application are all arranged inside the sub-pixel unit, and the protrusions on the second spacer layers 20 are filled inside the grooves, and the protrusions formed by the filling of the second spacer layers 20 will not be formed at the outer side of the sub-pixel units.

In an embodiment of the present application, the first spacer layers 10 and the second spacer layers 20 are usually made of organic materials, but the first spacer layers 10 are made of hydrophilic materials, and the second spacer layers 20 are made of hydrophobic materials. The second spacer layers 20 made of hydrophobic material can isolate inks of different colors and avoid color mixing. Meanwhile, the second spacer layers 20 made of hydrophobic material make the ink of inkjet printing flow along the edge of the second spacer layers 20 during subsequent vacuum drying without penetrating into the inside of the second spacer layers 20.

In an embodiment of the present application, a groove is formed on the sub-pixel units, and the protruding portion on the second spacer layers 20 is filled inside the groove, so that when vacuum drying is performed, the flow path of ink for inkjet printing is changed from the original straight line to curve, increasing the distance the ink flows. In this way, under the same drying conditions and drying time, the distance that the ink moves is reduced; the ink is not easy to move from the center to the edge of the sub-pixel unit, thereby reducing the mura phenomenon.

Further, since the sub-pixel units in the present application are arranged in the non-display area of the display panel, and the sub-pixel units in the present application can be used to reduce abnormal sub-pixel units, thereby reducing the width of the non-display area, so as to achieve a panel design with a narrow border.

As shown in FIG. 6, FIG. 6 is a schematic diagram of vacuum drying provided in an embodiment of the present application; wherein “hydrophobic” means that the spacer layer is made of a hydrophobic material, and “taper angle” refers to a size of an inclination angle formed by the spacer layer made in an embodiment of the present application, “slope width” refers to a width of a slope corresponding to the formed protrusion. In FIG. 6, under an original dry condition of the ink, a volatilization rate of the ink at an outer side is faster. After the solution evaporates, the ink in a center of the pixel will move to an edge, and the replenished ink will exacerbate a coffee ring effect, which in turn leads to uneven film surface at periphery of the pixels. With the sub-pixel units provided by the embodiment of the present application, a groove is formed in the sub-pixel units on the side close to the second spacer layers 20, and the second spacer layers fill the inside of the groove to form a protrusion. The protruding part of the second spacer layers 20 will cause resistance to the flow of ink, hinder the flow of ink from the center of the pixel to the edge, and reduce the flow rate of the ink, thereby reducing the problem of uneven pixel film surface.

It should be noted that, in an embodiment of the present application, protrusions are formed on the second spacer layers to protrude inside the sub-pixel units, so that grooves are formed inside the sub-pixel units, and the channel formed by the second spacer layers 20 is changed. The ink drips near the second spacer layers 20 and flows inside the sub-pixel units; when the channel formed by the second spacer layers 20 changes, a flow path of the ink will also change accordingly.

As shown in FIG. 7, FIG. 7 is a schematic diagram of the display panel provided by another embodiment of the present application. Referring to FIGS. 5 and 7 in conjunction, in the display panel in an embodiment of the present application, the sizes of the first spacer layers 10, the second spacer layers 20, the protrusions, and the sub-pixels in the display panel need to comply with preset size conditions.

In FIG. 7, a width of each of the first spacer layers 10 in the vertical direction is L2, that is, the width of each of the sub-pixel units in the vertical direction is L2; and a width of each of the sub-pixel units in the vertical direction is L1 after deducting the groove portion. Meanwhile, in the pixel of a same row, a length of any one of the sub-pixel units in the horizontal direction is W2, and a length of any one of grooves in the horizontal direction is W1.

In an embodiment of the present application, when L1/L2 is greater than a first preset value, it can be considered that the channel through which the ink flows in the vertical direction is wider; in this case, the channel needs to be kept short, that is, W1/W2 is smaller than a second preset value.

The first preset value may be 55%, and the second preset value may be 35%. That is, when L1/L2 is greater than 55%, it is considered that the channel through which the ink flows in the vertical direction is wider; and when W1/W2 is less than 35%, it is considered that the channel through which the ink flows in the vertical direction is shorter.

When L1/L2 is less than a third preset value, it can be considered that the channel through which the ink flows is relatively narrow; in this case, the channel needs to be kept longer, that is, W1/W2 is greater than a fourth preset value.

The third preset value may be 40%, and the fourth preset value may be 50%. That is, when L1/L2 is less than 40%, it is considered that the channel through which the ink flows in the vertical direction is relatively narrow; and when W1/W2 is greater than 50%, it is considered that the channel through which the ink flows in the vertical direction is longer.

In an embodiment of the present application, usually, the third preset value is smaller than the first preset value, and the fourth preset value may be greater than the second preset value.

In an embodiment of the present application, each of the sub-pixel units is usually prepared as a narrow and long structure, so that in the same time, the channel through which the ink flows is narrower, and a flow distance of the ink becomes longer, which can effectively slow down a flow rate of the ink.

In a specific embodiment, L1 may be 14 μm, and L2 may be 48 μm; and W1 may be 136 μm, and W2 may be 186 μm. In this case, L1/L2 is approximately equal to 30%, and under the premise that L1/L2 is less than 40%, W1/W2 is approximately equal to 73%, which is greater than 50%.

As shown in FIG. 8, FIG. 8 is a design diagram of a non-display area of a product prepared by a display panel provided by an embodiment of the present application. Referring to FIG. 5, FIG. 7 and FIG. 8 in conjunction. In the embodiment shown in FIG. 8, protruding directions of at least two protruding portions of the plurality of protrusions disposed in the plurality of second spacer layers in the same row are different; and a position on each of the sub-pixel units corresponding to each of the protrusions may correspondingly form one of the grooves, so opening directions corresponding to the grooves are also different.

In the embodiment shown in FIG. 5, the plurality of protrusions in different protruding directions in the plurality of second spacer layers located in the same row may intersect each other. In this case, a plurality of grooves with different opening directions located in the same row may also intersect each other. Meanwhile, in the embodiment shown in FIG. 5, the protruding directions of at least two of the plurality of protrusions provided in the plurality of second spacers in the same column may be the same. Correspondingly, the opening directions of at least two of the plurality of grooves located in the same row may also be the same. Specifically, the plurality of protrusions located in the same column may be arranged upward in the vertical direction at the same time, or the plurality of protrusions may be arranged downward in the vertical direction at the same time. In this case, the plurality of grooves located in the same row may simultaneously open downwards or simultaneously open upwards.

Referring to FIG. 5 and FIG. 6, when a plurality of protrusions are formed, if vacuum drying is performed, a part of the second spacer layers 20 filled in the groove with the opening downward will block the flow of ink. Meanwhile, the part of the second spacer layers 20 filled in the groove with the opening downward narrows the channel through which the ink flows, so that a volume of the ink flowing through the channel in a same duration of time becomes smaller. In an embodiment of the present application, the protrusions in different protruding directions intersecting each other can further reduce a flow speed of the ink.

In the embodiments of the present application, the protrusions can be in various shapes such as a semicircle, a semi-ellipse, a rectangle, a rounded rectangle, a triangle, and a trapezoid, and the shapes and sizes of the protrusions can be adjusted according to actual requirements for an aperture ratio of the pixel.

As shown in FIG. 9, FIG. 9 is a schematic diagram of the display panel provided by another embodiment of the present application. In FIG. 9, the shape of the protrusion can be a rounded rectangle; that is, four corners of the rectangle are arcs. FIG. 10 is a schematic diagram of a display panel provided by a further embodiment of the present application. In FIG. 10, the shape of the protrusion may be a rectangle. In the embodiments shown in FIGS. 11 and 12, the shapes of the protrusions are trapezoidal and triangular, respectively. Of course, In an embodiment of the present application, a shape of the groove and a shape of the protrusion are matched with each other, and when the protrusion is a rectangle with rounded corners, a protrusion of the groove is also a rectangle with rounded corners.

In an embodiment of the present application, an object is to increase the flow path of the ink and set a barrier to inhibit the flow of the ink; that is, to increase a loss of the ink during the ink flows. Specifically, the loss of the ink along the flow path can satisfy the following formula: loss along the flow path L=k/r−(k*X)/A.

In the above formula, k is a fixed parameter, and the parameter k varied with different display panels; r is a hydraulic radius, which refers to a ratio of a flow area of a certain liquid delivery section to a side length of a liquid delivery pipeline (i.e. a wet circumference) that is in contact with a liquid body, and r is related to a shape of a section and is often used to calculate a liquid delivery capacity of a channel tunnel.

Therefore, r=X/A, where A is an effective section through which the liquid flows, and X is the wet circumference. The grooved with different shapes correspond to different effective cross-sections and wet circumferences.

In the embodiments of the present application, when the shape of the protrusion is semicircular or semi-elliptical, it has a small effect on a flow rate of the ink; and when the shape of the protrusion is triangular or rectangular, it has a more obvious inhibitory effect on the flow rate of the ink.

Referring to FIG. 13, FIG. 13 is a schematic diagram of a plurality of grooves of different shapes provided by an embodiment of the present application. In FIG. 13, sizes of the grooves of various shapes in the vertical direction are the same, that is, channel widths corresponding to the grooves of various shapes are the same. On the premise of the same channel width, when the shape of the groove is a rounded rectangle, the wet circumference X corresponding to the groove is the largest, that is, a distance through which the ink flows is the largest. In this way, in the same time, the ink is less likely to spread from the center.

It should be noted that, in an embodiment of the present application, the ink flows inside the accommodating space formed by the intersection of the first spacer layers 10 and the second spacer layers 20, instead of flowing inside the channel formed by the first spacer layers 10 and the second spacer layers 20.

That is, in an embodiment of the present application, not only the size of the groove, but also the specific shape of the groove need to be considered; the size of the groove and the specific shape of the groove will affect the flow of ink.

In the above embodiments, the descriptions of each embodiment have their own emphasis. The parts that are not described in detail in an embodiment can be referred to the detailed descriptions in other embodiments above, which will not be repeated herein for brevity.

In specific implementation, each of the above units or structures may be implemented as independent entities, or may be implemented as any combination as the same or several entities. The specific implementation of the above units or structures can be referred to the foregoing method embodiments, which will not be repeated herein for brevity.

Specific implementation of the above operations can be referred to the previous embodiments, which will not be repeated herein for brevity.

The display panel and the display device provided by the embodiments of the present invention have been described in detail above. Specific examples are used to explain the principle and implementation of the present application. The descriptions of the above embodiments are only used to help understand the present application. Also, for those skilled in the art, according to the ideas of the present application, there will be changes in the specific implementation and application scope. In summary, the content of this specification should not be construed as limiting the present application.

1. A display panel, wherein the display panel comprises a plurality of first spacer layers extending in a first direction and a plurality of second spacer layers extending in a second direction, the first spacer layers and the second spacer layers define a plurality of sub-pixel units, the plurality of second spacer layers are configured to separate the sub-pixel units of different colors, and the first direction is perpendicular to the second direction; and
wherein a protrusion is formed on at least one of the plurality of second spacer layers, and the protrusion is protruded in one of the sub-pixel units.

2. The display panel according to claim 1, wherein the plurality of first spacer layers are configured to separate the plurality of sub-pixel units located in a same row; the plurality of sub-pixel units located in the same row have a same color; and colors corresponding to the plurality of sub-pixel units located in a same column are arranged cyclically.

3. The display panel according to claim 2, wherein each of the first spacer layers is located between adjacent ones of the sub-pixel units in the same row, and each of the second spacer layers is located between adjacent ones of the sub-pixel units in the same column; the plurality of first spacer layers form a first channel in the display panel, the plurality of second spacer layers form a second channel in the display panel, and a protruding direction of the protrusion is same as an extending direction of the first channel.

4. The display panel according to claim 3, wherein the protrusion is formed on all of the second spacer layers.

5. The display panel according to claim 4, wherein each of the second spacer layers comprises a protruding portion and a flat portion, the protruding portion is protruded in each of the sub-pixel units, and the flat portion is connected to the second channel.

6. The display panel according to claim 5, wherein protruding directions of at least two protruding portions of the plurality of protrusions disposed in the plurality of second spacer layers in the same row are different.

7. The display panel according to claim 5, wherein protruding directions of at least two protruding portions of the plurality of protrusions disposed in the plurality of second spacer layers in the same column are same.

8. The display panel according to claim 1, wherein the first spacer layers are made of a hydrophilic material, and the second spacer layers are made of a hydrophobic material.

9. The display panel according to claim 1, wherein the protrusion is semicircular, semi-elliptical or rectangular.

10. The display panel according to claim 1, wherein a groove is formed inside each of the sub-pixel units, and a shape of the groove and a shape of the protrusion are matched with each other.

11. A display device, wherein the display device comprises the display panel according to claim 1; the display panel comprises a plurality of first spacer layers extending in a first direction and a plurality of second spacer layers extending in a second direction, the first spacer layers and the second spacer layers define a plurality of sub-pixel units, the plurality of second spacer layers are configured to separate the sub-pixel units of different colors, and the first direction is perpendicular to the second direction; and
wherein a protrusion is formed on at least one of the plurality of second spacer layers, and the protrusion is protruded in one of the sub-pixel units.

12. The display device according to claim 11, wherein the plurality of first spacer layers are configured to separate the plurality of sub-pixel units located in a same row; the plurality of sub-pixel units located in the same row have a same color; and colors corresponding to the plurality of sub-pixel units located in a same column are arranged cyclically.

13. The display device according to claim 12, wherein each of the first spacer layers is located between adjacent ones of the sub-pixel units in the same row, and each of the second spacer layers is located between adjacent ones of the sub-pixel units in the same column; the plurality of first spacer layers form a first channel in the display panel, the plurality of second spacer layers form a second channel in the display panel, and a protruding direction of the protrusion is same as an extending direction of the first channel.

14. The display device according to claim 13, wherein the protrusion is formed on all of the second spacer layers.

15. The display device according to claim 14, wherein each of the second spacer layers comprises a protruding portion and a flat portion, the protruding portion is protruded in each of the sub-pixel units, and the flat portion is connected to the second channel.

16. The display device according to claim 15, wherein protruding directions of at least two protruding portions of the plurality of protrusions disposed in the plurality of second spacer layers in the same row are different.

17. The display device according to claim 15, wherein protruding directions of at least two protruding portions of the plurality of protrusions disposed in the plurality of second spacer layers in the same column are same.

18. The display device according to claim 11, wherein the first spacer layers are made of a hydrophilic material, and the second spacer layers are made of a hydrophobic material.

19. The display device according to claim 11, wherein the protrusion is semicircular, semi-elliptical or rectangular.

20. The display device according to claim 11, wherein a groove is formed inside each of the sub-pixel units, and a shape of the groove and a shape of the protrusion are matched with each other.
